(19) United States
(12) Patent Application Publication
(10) Pub. No.: US 2008/0066898 A1
(43) Pub. Date: Mar. 20, 2008

(54) Heat dissipation device

(75) Inventors: Cheng-Tien Lai, Tu-Cheng (TW); Wei-Le Wu, Shenzhen (CN); Cui-Jun Lu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Foxconn Technology Co., Ltd., Tu-Cheng City (TW)

(21) Appl. No.: 11/521,919

(22) Filed: Sep. 15, 2006

(51) Int. Cl. H05K 7/20

(52) U.S. Cl. 165/185; 361/697; 165/80.3

(57) ABSTRACT

A heat dissipation device includes a heat conducting core having a heat receiver and a column extending from the heat receiver. A first fin unit includes a plurality of first fins radially extending from the core. The first fins curve along an anticlockwise direction. A plurality of first passages is defined between the first fins. A second fin unit includes a plurality of second fins radially extending from the core. The second fins curve along a clockwise direction. A plurality of second passages is defined between the second fins and communicating with the first passages of the first fin unit. A fan is positioned on the second fin unit for providing forced airflow to the second passages of the second fin unit and then the first passages of the first fin unit. The fan rotates anticlockwise.

### BACKGROUND OF THE INVENTION

1. Field of the Invention

The present invention relates generally to a heat dissipation device, and more particularly to a heat dissipation device used for dissipating heat generated by an electronic device.

2. Description of Related Art

With advancement of computer technology, electronic devices are achieving ever higher operating speeds. It is well known that the faster electronic devices operate, the more heat they generate. If the heat is not quickly dissipated, the operation of the electronic devices will suffer instability or even malfunction. Generally, in order to ensure normal running of the electronic device, a heat dissipation device is used to dissipate the heat generated by the electronic device.

One common method of cooling the electronic device includes thermally coupling a heat sink to the electronic device. A typical heat sink includes a plurality of fins extending from a flat base of the heat sink. A fan is often used in conjunction with the heat sink to improve heat dissipation efficiency of the heat sink. The fan, which is typically mounted near the heat sink, causes air to move past the fins of the heat sink. Moving air past the heat sink increases the rate of convection between the heat sink and the ambient environment wherein the heat sink is located. Increasing the rate of convection between the heat sink and the ambient environment reduces the temperature of the heat sink, thereby enhancing heat dissipating capacity of the heat sink. However, with the trend of great density and small sizes of the electronic devices, it is difficult for the heat sink to increase its size. The heat sinks must be relatively compact in size and must perform well enough to prevent high-performance electronic devices from exceeding their operational heat specifications. Therefore, a specially-configured heat sink is developed to dissipate heat for the electronic devices. Referring to FIG. 5, a heat sink in accordance with related art includes a heat conducting central core 1 and a heat dissipating body 3 surrounding and thermally connecting with the core 1. Pluralities of helical fins 4 radially extend from a circumferential face of the body 3. A plurality of passages (not labeled) is defined between the fins 4. A fan 6 is mounted atop of the fins 4 via a fan holder 7 which is secured to the fins 4. In use, the heat sink is secured to the electronic device via a locking device 5 with a bottom of the core 1 contacting the electronic device. In the heat sink of FIG. 5, the fins 4 extend along a clockwise direction, while the fan 6 rotates along a counterclockwise direction. The heat generated by the electronic device is transferred to the fins 4 by the core 1 and be dissipated to the ambient environment by the fins 4 under work of the fan 6. However, in the heat sink, airflow provided by the fan 6 flows out of the passages without sufficient heat exchange with the fins 4. Therefore, the heat sink needs to be improved to meet the more and more heat generated by the up-to-date electronic devices.

What is needed, therefore, is a heat dissipation device having great heat dissipating capacity for electronic devices.

### SUMMARY OF THE INVENTION

A heat dissipation device in accordance with a preferred embodiment of the present invention comprises a heat conducting core having a heat receiver and a column extending upwardly from the heat receiver. A first fin unit comprises a plurality of first fins radially extending from the core. The first fins curve along an anticlockwise direction. A plurality of first passages is defined between the first fins. A second fin unit comprises a plurality of second fins radially extending from the core. The second fins curve along a clockwise direction. A plurality of second passages is defined between the second fins and communicating with the first passages of the first fin unit. The first and second fin units are mounted on the column with the second fin unit located above the first fin unit. A fan is positioned on the second fin unit for providing forced airflow to the second passages of the second fin unit and then the first passages of the first fin unit.

Other advantages and novel features will become more apparent from the following detailed description of preferred embodiments when taken in conjunction with the accompanying drawings, in which:

### BRIEF DESCRIPTION OF THE DRAWINGS

Many aspects of the present apparatus and method can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is an exploded, isometric view of a heat dissipation device in accordance with a preferred embodiment of the present invention;

FIG. 2 shows an assembled heat sink of FIG. 1;

FIG. 3 is top plan view of FIG. 2;

FIG. 4 is an assembled view of FIG. 1; and

FIG. 5 is a heat dissipation device in accordance with related art.

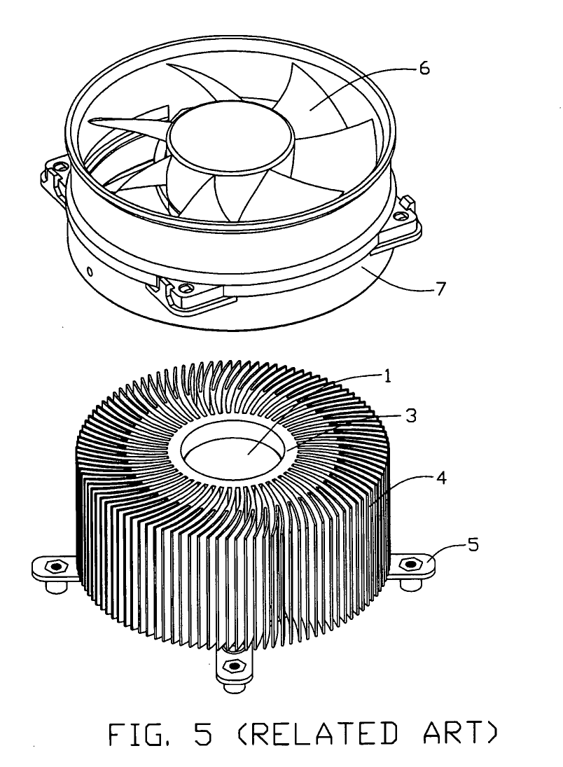

### DETAILED DESCRIPTION OF THE INVENTION

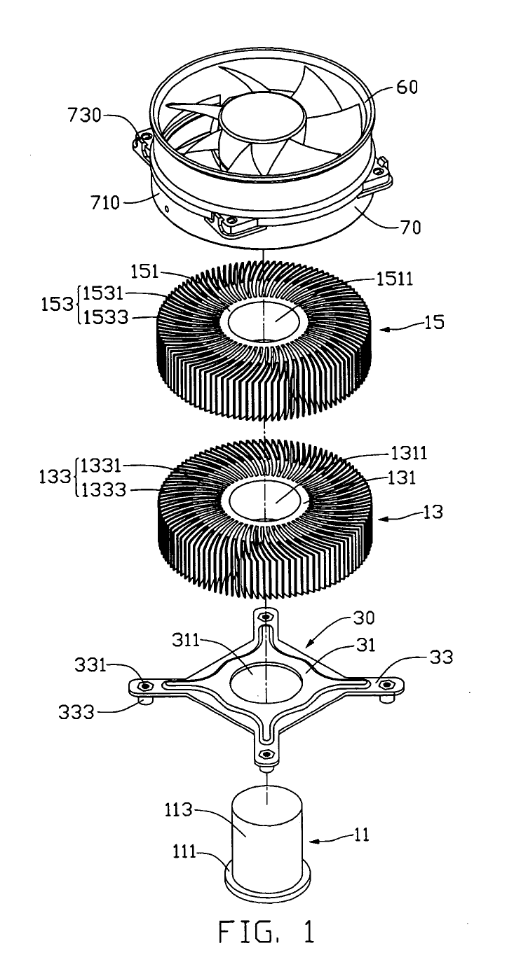

Referring to FIG. 1, a heat dissipation device in accordance with a preferred embodiment of the present invention is shown. The heat dissipation device comprises a heat sink having a heat conducting core 11 and first, second fin units 13, 15 surrounding the core 11, a locking device 30 engaged with the heat sink for securing the heat sink to an electronic device (not shown) located on a printed circuit board (not shown), and a fan 60 located on the heat sink via a holder 70.

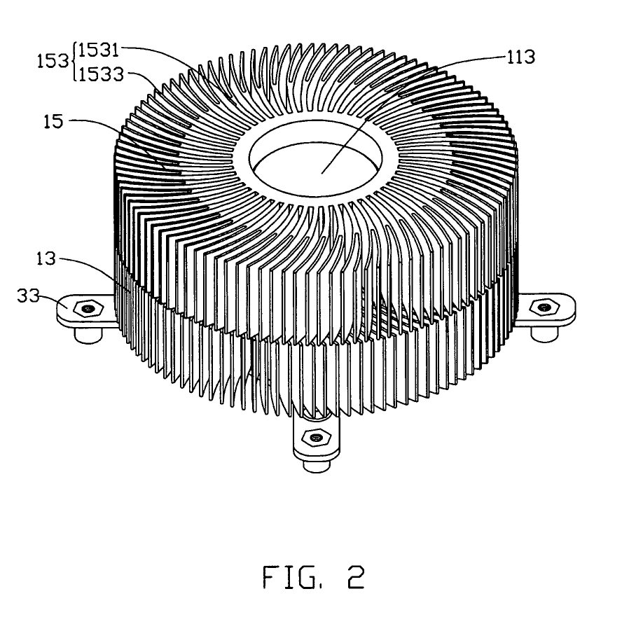

Referring also to FIG. 2, the core 11 of the heat sink is made of metal having excellent heat conducting property, for example, copper. The core 11 comprises an expanding circular heat receiver 111 at a bottom thereof, for thermally contacting with the electronic device, and a column 113 extending upwardly from the heat receiver 111.

The first fin unit 13 is formed by aluminum extrusion and comprises a cylindrical collar 131 and a plurality of helical first fins 133 extending radially and outwardly from a circumferential face of the collar 131. A first receiving hole 1311 is defined through the first fin unit 13 and is surrounded by the collar 131, for interferentially accommodating the column 113 of the core 11 therein. Each of the first fins 133 anticlockwise curves along a circumferential direction of the collar 131. Each of the first fins 133 comprises a trunk 1331 and a pair of tines 1333 divided from the trunk 1331 at an outer portion of the respective first fin 133. The dividing of each first fin 133 into the tines 1333 occurs at a bifurcate point that may, for example, be about halfway along the length of the first fins 133. Each trunk 1331 has a root (not labeled) emerging in an outward direction from the collar 131, and each tine 1333 has a root (not labeled) emerging in an outward direction from the bifurcate point thereof. Each tine 1333 also has a tip at an end of the tin 1333 opposite the tine root. For each first fin 133, it can be considered as having two tips formed by the tines. The length of the first fin 133 is defined by the curvilinear distance along the first fin 133 from the root of the trunk 1331 to either of the tips of the two tines 1333 of the first fin 133. Each first fin 133 has a convex surface (not labeled) extending from the root of the trunk 1331 to the tip of one of the tines 1333 of the first fin 133. Each first fin 133 also has a concave surface (not labeled) opposite to the convex surface and extending from the root of the trunk 1331 to the tip of the other one of the tines 1333 of the first fin 133. A plurality of first passages (not labeled) is defined between the adjacent trunks 1331 and the adjacent tines 1333 of the first fins 133 for airflow flowing therethrough.

The second fin unit 15 is similar to the first fin unit 13, and comprises a plurality of second fins 153; however, each of the second fins 153 clockwise curves along a circumferential direction of a collar 151 thereof. A second receiving hole 1511 is defined through a center of the second fin unit 15 for accommodating the column 113 of the core 11 therein. Each of the second fins 153 comprises a trunk 1531 and a pair of tines 1533 splits from the trunk 1531 at about halfway along the length thereof. A plurality of second passages (not labeled) is defined between the adjacent trunks 1531 and the adjacent tines 1533 of the second fins 153.

The locking device 30 comprises a substantially rectangular locking plate 31 and four locking legs 33 extending from four corners of the plate 31, respectively. An opening 311 is defined in a center of the plate 31 for the column 113 of the core 11 to extend therethrough. A diameter of the opening 311 is smaller than that of the heat receiver 111 but substantially equal to that of the column 113 of the core 11. Each of the legs 33 defines a screw aperture 331 therein for accommodating a fastener (not shown) therein to fasten the heat dissipation device to the printed circuit board so that a bottom face of the heat receiver 111 can have an intimate contact with the electronic device. A sleeve 333 depends from each of the legs 33 under the screw aperture 331. The sleeves 333 are used for guiding the movement of the fasteners.

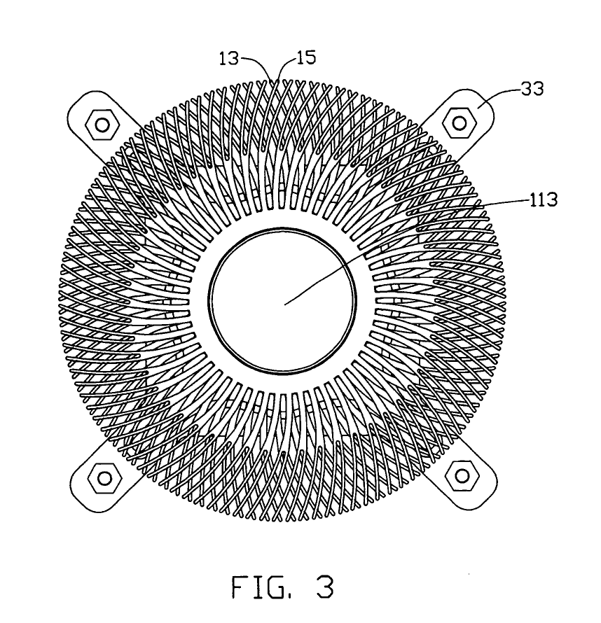

Referring also to FIGS. 2 and 3, the column 113 of the core 11 extends through the opening 311 of the locking device 30, and then is interferentially accommodated in the holes 1311, 1511 of the first and second fin units 13, 15, with the first fins 133 radially extending from the column 113 of the core 11 along an anticlockwise direction and the second fins 153 radially extending from the column 113 along a clockwise direction. Therefore, the heat sink and the locking device 30 are assembled together. The heat receiver 111 is located under the locking plate 31 of the locking device 30. The first fin unit 13 is positioned on the locking plate 31 of the locking device 30. The second fin unit 15 is located on the first fin unit 13, with the first passages of the first fin unit 13 in communication with the second passages of the second fin unit 15.

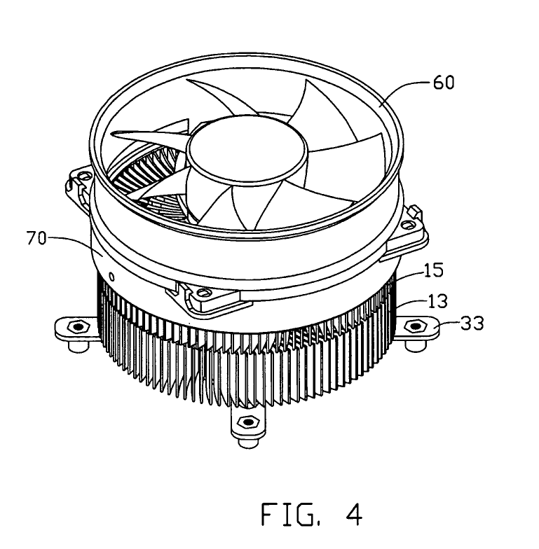

Referring to FIGS. 1 and 4, the fan 60 is attached to the heat sink via a holder 70 attached to the second fin unit 15. The fan 60 has a circular profile. The holder 70 comprises an annular main body 710 surrounding a periphery of an upper portion of the second fins 153 of the second fin unit 15, and a plurality of supports 730 evenly extending from an upper portion of the periphery of the main body 710. The supports 730 fix the fan 60 on the holder 70. Therefore, the fan 60 is positioned atop the second fin unit 15 and confronts the second and first passages of the second and first fin unit 15, 13.

In use, the heat dissipation device is attached to the electronic device with the heat receiver 111 of the heat sink thermally contacting the electronic device. The heat generated by the electronic device is absorbed by the heat receiver 111, and then is transferred to the first and second fin units 13, 15 via the column 113 of the core 11. The fan 60 provides forced airflow to the second and first fin units 15, 13. The airflow from the fan 60 passes through the second and first passages of the second and first fin units 15, 13 and removes the heat in the second fins 153 and the first fins 133 to ambient air. According to this preferred embodiment, the fan 60 is operated to rotate anticlockwise.

Table 1 below shows temperature data obtained from laboratory tests of the heat dissipation device of the related art and the heat dissipation device of the present invention. The tests were conducted with the environment temperature being Ta. Tc represents the temperature that the heat generating electronic device operates with the related heat dissipation device or the heat dissipation device of the present invention. The table shows that heat resistance θ of the heat dissipation device of the present invention is always lower than heat resistance θ of the related heat dissipation device under the same condition. That is to say, heat dissipation efficiency of the instant heat dissipation device of the present invention is higher than that of the related heat dissipation device. In the table, letter A denotes the related heat dissipation device, while letter B denotes the heat dissipation device of the present invention. Letter M denotes the first fin unit 13 of the heat dissipation device of the present invention; letter N denotes the second fin unit 15 of the heat dissipation device of the present invention.

TABLE 1

| | Fan | | Source | Height | | | | | |
|---|---|---|---|---|---|---|---|---|---|
| | | Speed | Power | (mm) | | | | | θ (° C./ |
| Sample | Model | (rpm) | (watt) | M | N | Ta (° C.) | Tc (° C.) | ΔT (° C.) | watt) |
| A | Foxconn | 4000 | 100.86 | 40 | | 34.3 | 61.6 | 27.3 | 0.2707 |
| | | | | | | 32.5 | 60.2 | 27.7 | 0.2746 |
| | | | | | | 34.8 | 62.6 | 27.8 | 0.2756 |
| | | | | | | 32.3 | 60.1 | 27.8 | 0.2756 |
| B | | | | 20 | 20 | 32.8 | 58.9 | 26.1 | 0.2588 |
| | | | | | | 32.7 | 59.0 | 26.3 | 0.2608 |
| | | | | | | 33.4 | 59.9 | 26.5 | 0.2627 |
| | | | | | | 32.1 | 58.1 | 26.0 | 0.2578 |
| | | | | 15 | 25 | 32.8 | 59.4 | 26.6 | 0.2637 |
| | | | | | | 32.4 | 58.2 | 25.8 | 0.2558 |
| | | | | | | 33.3 | 59.4 | 26.1 | 0.2588 |
| | | | | | | 32.7 | 58.7 | 26.0 | 0.2578 |
| | | | | 25 | 15 | 32.1 | 58.9 | 26.8 | 0.2657 |
| | | | | | | 32.1 | 58.2 | 26.1 | 0.2588 |
| | | | | | | 30.3 | 57 | 26.7 | 0.2647 |
| | | | | | | 32.4 | 59.2 | 26.8 | 0.2657 |

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a heat conducting core comprising a heat receiver and a column extending from the heat receiver;
a first fin unit comprising a plurality of first fins radially extending from the column of the core and curved along a first direction, a plurality of first passages being defined between the first fins; and
a second fin unit comprising a plurality of second fins radially extending from the column of the heat conducting core and curved along a second direction opposite from the first direction, a plurality of second passages being defined between the second fins and communicating with the first passages of the first fin unit.

2. The heat dissipation device of claim 1, wherein the first fins of the first fin unit radially extend from the column of the core and curved along an anticlockwise direction, while the second fins of the second fin unit radially extend from the column of the core and curved along a clockwise direction.

3. The heat dissipation device of claim 2, wherein the first fins each has a trunk and two tines splitting from an outer end of the trunk.

4. The heat dissipation device of claim 2, wherein the second fins each has a trunk and two tines splitting from an outer end of the trunk.

5. The heat dissipation device of claim 2 the first fin unit comprises a cylindrical collar defining a hole accommodating the column of the core therein, the first fins radially extending from a circumferential face of the collar.

6. The heat dissipation device of claim 2, wherein the second fin unit comprises a cylindrical collar defining a hole accommodating the column of the core therein, the second fins radially extending from a circumferential face of the collar.

7. The heat dissipation device of claim 2 further comprising a locking device located between the heat receiver and the first unit, adapted for fixing the heat dissipation device to a printed circuit board.

8. The heat dissipation device of claim 7, wherein the locking device comprises a locking plate and a plurality of fixing legs extending from the locking plate, the column of the heat conducting body extending through an opening of the locking plate, the heat receiver of the heat conducting body located below the locking plate.

9. The heat dissipation device of claim 2 further comprising a fan for providing forced airflow to the second passages of the second fin unit and then the first passages of the first fin unit.

10. The heat dissipation device of claim 9, wherein the fan is attached atop the second fin unit via a holder secured to the second fin unit.

11. A heat dissipation device comprising:
a heat conducting core;
a first fin unit comprises a plurality of first fins radially extending from the core, the first fins curving along an anticlockwise direction, a plurality of first passages being defined between the first fins;
a second fin unit comprises a plurality of second fins radially extending from the core, the second fins curving along a clockwise direction, a plurality of second passages being defined between the second fins and communicating with the first passages of the first fin unit; and
a fan for providing forced airflow to the second passages of the second fin unit and then the first passages of the first fin unit.

12. The heat dissipation device of claim 11, wherein the core comprises a column extending through the first fin unit and the second fin unit, and a heat receiver formed at an end of the column near the first fin unit, the heat receiver being adapted for contacting with an electronic device.

13. The heat dissipation device of claim 12 further comprising a locking device mounted to column of the core and located between the heat receiver and the first fin unit.

14. The heat dissipation device of claim 11, wherein the fan is attached atop the second fin unit via a holder secured to the second fin unit.

15. The heat dissipation device of claim 11, wherein the first fins of the first fin unit each comprises a trunk extending from the core and two tines splitting from the trunk, the first passages being defined between adjacent trunks and adjacent tines of the first fins.

16. The heat dissipation device of claim 11, wherein the second fins of the second fin unit each comprises a trunk extending from the core and two tines splitting from the trunk, the second passages being defined between adjacent trunks and adjacent tines of the second fins.

17. The heat dissipation device of claim 11, wherein the fan rotates anticlockwise.

18. A heat dissipation device comprising:
a central column having a bottom face adapted for thermally connecting with an electronic device to absorb heat therefrom;
a first fin unit having a plurality of first fins around the column, the first fins being curved along one of clockwise and counterclockwise directions;
a second fin unit having a plurality of second fins around the column, the second fins being located above the first fins and curved along the other one of clockwise and counterclockwise directions; and
a fan mounted above the second fin unit for generating an airflow through the second and first fin units, the fan being rotated along a direction different from the curved direction of the second fins of the second fin unit for generating the airflow.

19. The heat dissipation device of claim 18 further comprising a holder secured to the second fins of the fin unit, the fan being mounted on the holder.

20. The heat dissipation device of claim 18 further comprising an engaging device adapted for securing the heat dissipation device to a printed circuit board on which the electronic device is mounted, the engaging device being mounted to the column at a position between first fin unit and the bottom face of the column.
